(19) United States
(12) Patent Application Publication
(10) Pub. No.: US 2022/0122819 A1
(43) Pub. Date: Apr. 21, 2022

(54) SEMICONDUCTOR CHAMBER COMPONENTS FOR BACK DIFFUSION CONTROL

(71) Applicant: Applied Materials, Inc., Santa Clara, CA (US)

(72) Inventor: Mingle Tong, Sunnyvale, CA (US)

(73) Assignee: Applied Materials, Inc., Santa Clara, CA (US)

(21) Appl. No.: 17/071,683

(22) Filed: Oct. 15, 2020

(51) Int. Cl. H01J 37/32; C23C 16/52

(52) U.S. Cl. CPC H01J 37/32807; H01J 37/32449; H01J 37/32357; C23C 16/52

(57) ABSTRACT

Exemplary semiconductor processing systems may include a remote plasma source and a processing chamber. The processing chamber may include a gasbox defining an access into the processing chamber. The systems may include an adapter positioned between the remote plasma source and the processing chamber. The adapter may include a mounting block defining a central aperture. The remote plasma source may be seated on a first surface of the mounting block. The adapter may include a mounting plate characterized by a first surface on which the mounting block is seated. The mounting plate may define a central aperture axially aligned with the central aperture defined through the mounting block. The mounting plate may define a recess in the first surface of the mounting plate extending about the central aperture through the mounting plate. The recess may form a volume between the mounting block and the mounting plate.

### TECHNICAL FIELD

The present technology relates to components and apparatuses for semiconductor manufacturing. More specifically, the present technology relates to processing chamber distribution components and other semiconductor processing equipment.

### BACKGROUND

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Additionally, the way materials are flowed into a chamber may impact diffusion into the chamber, as well as back diffusion along separate flow paths.

Thus, there is a need for improved systems and methods that can be used to produce high-quality devices and structures. These and other needs are addressed by the present technology.

### SUMMARY

Exemplary semiconductor processing systems may include a remote plasma source. The systems may include a processing chamber. The processing chamber may include a gasbox defining an access into the processing chamber. The systems may include an adapter positioned between the remote plasma source and the processing chamber. The adapter may include a mounting block defining a central aperture. The remote plasma source may be seated on a first surface of the mounting block. The adapter may include a mounting plate. The mounting plate may be characterized by a first surface on which the mounting block is seated. The mounting plate may define a central aperture axially aligned with the central aperture defined through the mounting block. The mounting plate may define a recess in the first surface of the mounting plate extending about the central aperture through the mounting plate. The recess may form a volume between the mounting block and the mounting plate.

In some embodiments, the mounting block may include a first mounting block member on which the remote plasma source is seated. The first mounting block member may define a recess extending circumferentially about an outer surface of the first mounting block member. The mounting block may include a second mounting block member coupled with the first mounting block member. The second mounting block member may be seated on the mounting plate. The second mounting block member may define an aperture fluidly accessing the recess defined in the first mounting block member. The first mounting block member may be characterized by a second surface opposite the first surface of the mounting block. The first mounting block member may define a plurality of apertures extending from the recess defined in the first mounting block member to the second surface of the first mounting block member. The plurality of apertures may provide fluid access to the volume formed between the mounting block and the mounting plate.

The plurality of apertures defined in the first mounting block member may be fluidly accessible to the aperture defined through the second mounting block member via the recess defined circumferentially about the first mounting block member. The recess defined circumferentially about the first mounting block member may include a first recess portion and a second recess portion. The first recess portion may extend to a greater distance within the first mounting block member than the second recess portion. The second mounting block member may couple with the first mounting block member to provide a flow path between the second recess portion and the first recess portion. The first recess portion may be vertically offset from the aperture through the second mounting block member. The first recess portion may be fluidly accessible from the aperture through the second mounting block member via the second recess portion. The systems may include a valve providing fluid access to the aperture defined in the second mounting block member.

Some embodiments of the present technology may encompass semiconductor processing chamber adapters. The adapters may include a mounting block defining a central aperture. The mounting block may be characterized by a first surface and a second surface opposite the first surface. The adapters may include a mounting plate defining a central aperture axially aligned with the central aperture of the mounting block. The mounting plate may be characterized by a first surface and a second surface opposite the first surface. The second surface of the mounting block may be seated on the first surface of the mounting plate. The mounting plate may define a recess in the first surface of the mounting plate extending about the central aperture through the mounting plate. The recess may form a volume between the mounting block and the mounting plate.

In some embodiments, the mounting block may include a first mounting block member. The first mounting block member may define a recess extending circumferentially about an outer surface of the first mounting block member. The mounting block may include a second mounting block member coupled with the first mounting block member. The second mounting block member may be seated on the mounting plate. The second mounting block member may define an aperture fluidly accessing the recess defined in the first mounting block member. The first mounting block member may be characterized by a second surface opposite the first surface of the mounting block. The first mounting block member may define a plurality of apertures extending from the recess defined in the first mounting block member to the second surface of the first mounting block member. The plurality of apertures may provide fluid access to the volume formed between the mounting block and the mounting plate.

The plurality of apertures defined in the first mounting block member may be fluidly accessible to the aperture defined through the second mounting block member via the recess defined circumferentially about the first mounting block member. The recess defined circumferentially about the first mounting block member may include a first recess portion and a second recess portion. The first recess portion may extend to a greater distance within the first mounting block member than the second recess portion. The second mounting block member may couple with the first mounting block member to provide a flow path between the second recess portion and the first recess portion. The first recess portion may be vertically offset from the aperture through the second mounting block member. the first recess portion may be fluidly accessible from the aperture through the second mounting block member via the second recess portion.

Some embodiments of the present technology may encompass methods of semiconductor processing. The methods may include flowing a precursor into a processing region of a semiconductor processing system. A substrate may be seated on a substrate support within the processing region of a semiconductor processing chamber of the semiconductor processing system. The methods may include flowing an inert gas into a region defined between a remote plasma source and the semiconductor processing chamber. The region may include a bypass device. The bypass device may include an adapter positioned between the remote plasma source and the semiconductor processing chamber. The adapter may include a mounting block defining a central aperture. The remote plasma source may be seated on a first surface of the mounting block. The adapter may include a mounting plate. The mounting plate may be characterized by a first surface on which the mounting block is seated. The mounting plate may define a central aperture axially aligned with the central aperture defined through the mounting block. Flowing the inert gas may form an air curtain in the central aperture of the mounting plate between the processing chamber and the remote plasma source. The methods may include generating a plasma of the precursor within the processing region of the semiconductor processing chamber. The methods may include depositing a material on the substrate.

In some embodiments, the mounting plate may define a recess in the first surface of the mounting plate extending about the central aperture through the mounting plate. The recess may form a volume between the mounting block and the mounting plate. The methods may include adjusting a flow rate of the inert gas using an adjustable valve of the bypass device to adjust the air curtain to prevent back diffusion into the remote plasma source.

Such technology may provide numerous benefits over conventional systems and techniques. For example, embodiments of the present technology may limit or prevent back streaming into a remote plasma unit. Additionally, the components may allow an air curtain to be formed that may limit turbulence and maintain a flow profile through the processing chamber. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top view of an exemplary processing system according to some embodiments of the present technology.

FIG. 2 shows a schematic cross-sectional view of an exemplary plasma system according to some embodiments of the present technology.

FIG. 3 shows a schematic cross-sectional view of an exemplary processing system according to some embodiments of the present technology.

FIG. 4 shows a schematic cross-sectional view of an exemplary adapter according to some embodiments of the present technology.

FIG. 5 shows a schematic exploded view of an exemplary adapter according to some embodiments of the present technology.

FIG. 6 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

Some semiconductor processes form materials that produce fine particles that may flow back through the lid stack. These back streaming materials may deposit on upstream components. Some processing systems include a remote plasma source unit that is connected with the chamber, and that can deliver plasma effluents into the chamber, for cleaning processes as one example. Because the remote plasma source may be off during a deposition operation, a void space is created within the unit, and back streaming particles may flow into the remote plasma source. These materials may deposit on in the remote plasma source, and may cause damage or be incorporated during plasma generation operations. Some conventional technologies may attempt to prevent this interaction by using isolation valves or providing a purge through the remote plasma source. Isolation valves are expensive components, and may prohibitively add to system height when incorporated. Purging through the remote plasms source unit may also cause issues. For example, the remote plasma source may be a relatively large volume relative to the processing chamber. To provide an adequate purge through the volume, a higher purge volume and/or flow rate may be needed. This may create turbulent flow within the chamber, which may impact deposition processes occurring. Additionally, purging through the remote plasma source may entrain particles, such as aluminum fluoride, which may be deposited on the substrate being processed, causing defects or damage to the substrate.

The present technology overcomes these challenges by utilizing a downstream adapter that may provide a bypass flow upstream of the chamber, which may not flow through the remote plasma unit. The bypass flow may produce an air curtain to limit or prevent back streaming, while also providing a tunable flow into the processing chamber, which may be used to direct process precursors. By utilizing an adapter for the bypass flow, a lower flow rate and/or volume of purge may be used, which may facilitate deposition or other processing operations occurring.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

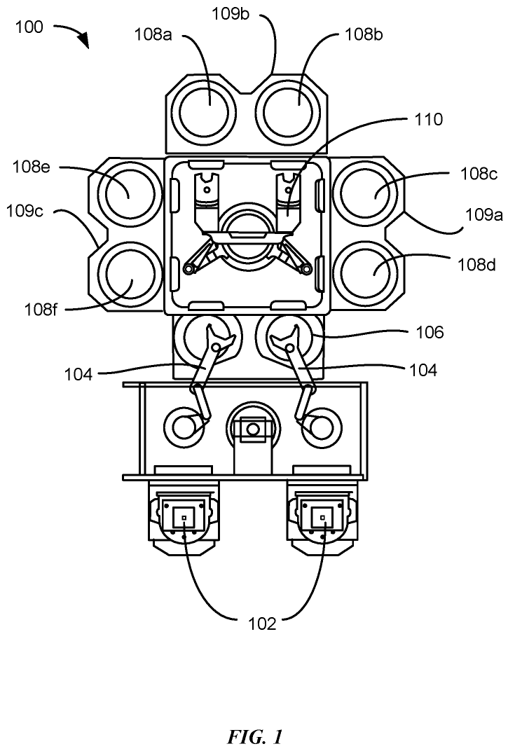

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

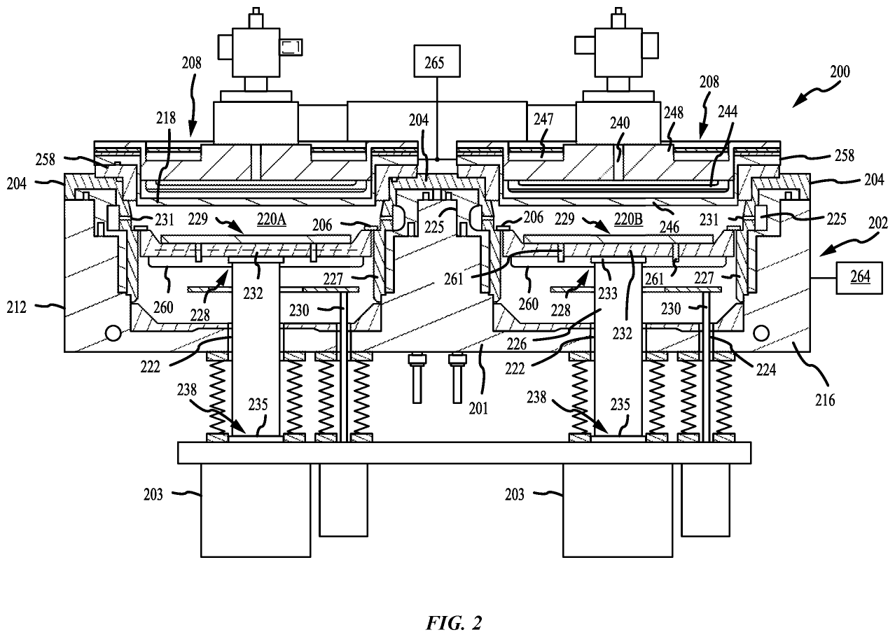

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

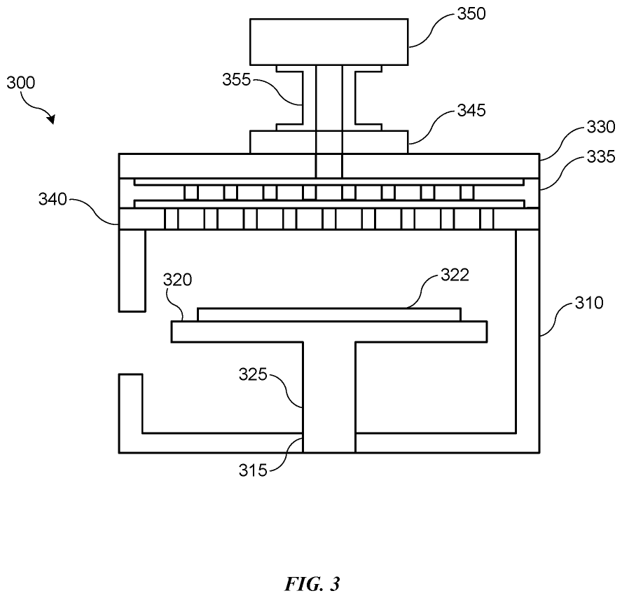

FIG. 3 shows a schematic partial cross-sectional view of an exemplary processing system 300 according to some embodiments of the present technology. FIG. 3 may illustrate further details relating to components in system 200, for example, and may introduce components discussed in more detail below. System 300 is understood to include any feature or aspect of system 200 discussed previously in some embodiments. The system 300 may be used to perform semiconductor processing operations including deposition of hardmask materials as previously described, as well as other deposition, removal, and cleaning operations. System 300 may show a partial view of the chamber components being discussed and that may be incorporated in a semiconductor processing system. Any aspect of system 300 may also be incorporated with other processing chambers or systems as will be readily understood by the skilled artisan.

System 300 may include a chamber body 310, which as illustrated may include sidewalls and a base, as well as a lid in some embodiments, all of which may at least partially define an internal volume that may include a processing region where a substrate may be processed. A pedestal or substrate support 315 may extend through the base of the chamber into the processing region as previously discussed. The substrate support may include a support platen 320, which may support semiconductor substrate 322. The support platen 320 may be coupled with a shaft 325, which may extend through the base of the chamber. System 300 may also include lid stack or gas distribution components positioned within or partially defining the interior volume of the chamber, which may facilitate delivery of processing precursors more uniformly through the chamber. The components may include a gasbox 330, which may receive a precursor through a gas delivery system through the lid of the chamber body.

A blocker plate 335 may operate as a choke in some embodiments to facilitate lateral or radial distribution of precursors through the component. The blocker plate 335 may be seated on a faceplate 340, which may define a plurality of apertures through the faceplate as illustrated, and through which precursors may be delivered to access the processing region and substrate. The faceplate may also be coupled with a power source for generating a plasma of the processing precursors within the processing region of the chamber. System 300 may include additional components outside of the processing chamber, which may provide access locations for precursors or fluids to be delivered into the chamber.

For example, an outlet manifold 345 may be positioned on the gasbox 330 or some other chamber component, and may provide fluid access into the chamber through a central aperture that may be axially aligned with a central aperture of the gasbox as illustrated. Although not illustrated, it is to be understood that outlet manifold 345 may be fluidly coupled with a weldment or inlet manifold that may provide precursors to the outlet manifold for distribution into the processing chamber. Additionally coupled with the outlet manifold 345 may be a remote plasma source unit 350, which may be seated on an adapter 355. While the outlet manifold may provide access or bypass channels into the processing chamber or to the central aperture for delivery precursors, the central aperture through the outlet manifold may be axially aligned with a central aperture through the adapter 355, and coupled with an outlet of the remote plasma source unit 350. During cleaning operations, or any other semiconductor process operations, the remote plasma source unit may generate plasma effluents to be delivered into the processing chamber for cleaning or other process operations. While the unit may be unused during some processing operations, the flow path to the remote plasma source unit may be maintained, which may allow access for back streaming particles to deposit. To limit this incursion, the present technology may provide a purge through adapter 355.

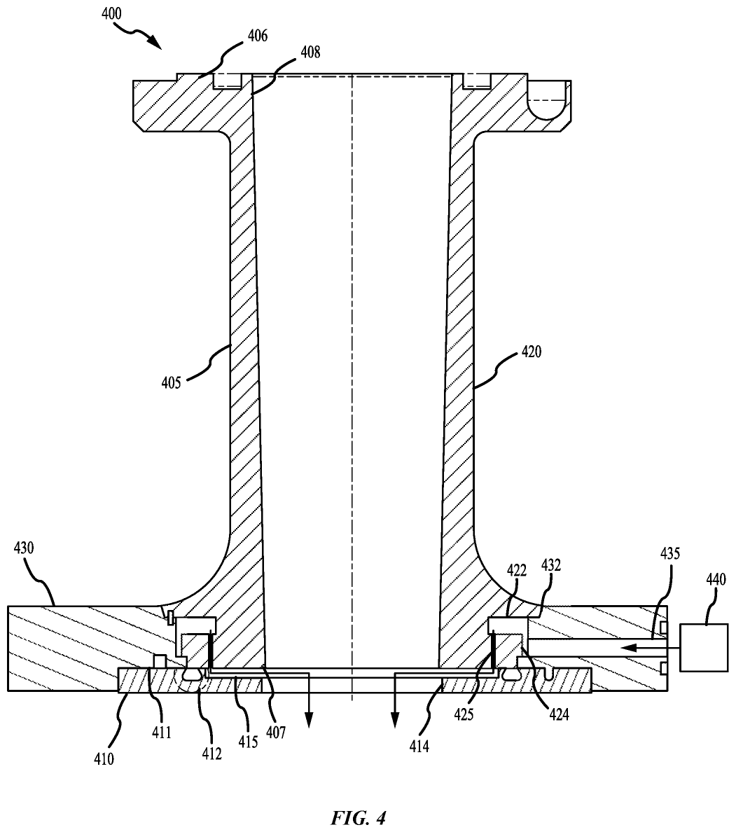

FIG. 4 shows a schematic cross-sectional view of an exemplary adapter 400 according to some embodiments of the present technology. Adapter 400 may be included in any processing system previously described, and may illustrate additional aspects of adapter 355 described above. Adapter 400 may include any feature, component or characteristics of adapters illustrated elsewhere, and may be included in any chamber system that may include an adapter seated in association with a processing chamber.

As illustrated, adapter 400 may include a mounting block 405 and a mounting plate 410, on which the mounting block 405 may be seated. Mounting block 405 may be characterized by a first surface 406 and a second surface 407 opposite the first surface. A remote plasma unit, such as remote plasma unit 350, may be seated on or coupled with first surface 406, while second surface 407 may be seated on mounting plate 410. Mounting block 405 may define a central aperture 408, which may extend through the mounting block and be axially aligned with a central aperture 414 through mounting plate 410. Mounting plate 410 may also be characterized by a first surface 411 on which the mounting block is seated, as well as a second surface 412 opposite the first surface. Within first surface 411, a recess 415 may be formed, which may extend about the central aperture 414, and form a volume as illustrated between the mounting block and the mounting plate.

As illustrated, in some embodiments mounting block 405 may include a first mounting block member 420 and a second mounting block member 430. First mounting block member 420 may be the component with which the remote plasma source unit may be coupled, and which may define a number of recesses that may define a purge flow path when the mounting block members are coupled with one another. As illustrated, first mounting block member 420 may define a first recess portion 422 and a second recess portion forming a shoulder 424 formed vertically from the second surface 407 of the first mounting block member. Shoulder 424 may define a second recess portion as shoulder 424 may be recessed from an outer edge of the first mounting block member at the second surface end of the mounting block. Extending through shoulder 424 of first mounting block member 420 may be a plurality of apertures 425 formed vertically through the first mounting block member 420 and extending from the first recessed portion 422 of the first mounting block member 420 to the second surface 407 of the mounting block. The plurality of apertures 425 may provide fluid access to the volume formed between the mounting block 405 and the mounting plate 410.

First recess portion 422 may be defined and extend circumferentially about an outer surface of the first mounting block member, which may provide a channel about the first mounting block in some embodiments. First recess portion 422 may extend to a greater distance radially inward on the first mounting block member than the second recess portion formed by shoulder 424. However, a flow path as described below may be formed by recessing shoulder 424 from an outer radial dimension from the second surface of the first mounting block member, which may be less than an outer radial dimension from the first surface of the first mounting block member.

Second mounting block member 430 may be characterized by a first surface or region that contacts first mounting block member 420, and a second surface that seats on mounting plate 410. For example, second mounting block member 430 may define a ledge 432 on which first mounting block member 420 seats. Shoulder 424 may also define a recessed ledge at the second surface 407 of the first mounting block member 420, within which second mounting block member 430 may extend. Second mounting block member 420 may have a protrusion that extends into the ledge, and which seats on mounting plate 410. Second mounting block member 430 may also define an aperture 435 extending laterally through the second mounting block. Aperture 435 may fluidly access the second recess formed by shoulder 424 as illustrated. For example, aperture 435 may extend laterally fully through second mounting block member 430, which may provide fluid access for delivery of a purge gas into the adapter. A valve 440 may be fluidly coupled between an inlet manifold and the adapter. The valve may be normally closed, which may limit back streaming of plasma effluents from the remote plasma source unit into the weldment when a purge is not being flowed.

Second mounting block member 430 may extend partially into first mounting block member 420, which may maintain a circumferential gap between the shoulder 424 and the second mounting block member 430, as illustrated. By seating into the first mounting block and maintaining a gap, a flow path may be formed that extends vertically away from the mounting plate 410. The flow path as illustrated may extend from aperture 435 into the recessed sections of first mounting block member 420, and may produce a flow path flowing vertically along shoulder 424 into first recessed portion 422. With apertures 425, a flow path may be produced that extends from valve 440, through aperture 435, and into the circumferential channel formed, and which may access the volume between the mounting block 405 and the mounting plate through apertures 425. As shown, first recessed portion 422 may be vertically offset from aperture 435 through second mounting block member 430. First recessed portion 422 may be fluidly accessible to the aperture 435 via the vertical access formed by the shoulder about the mounting block. The flow may continue along recessed portion 415 of mounting plate 410, and be delivered into central aperture 414.

The flow path may ensure the first recessed portion 422 may be circumferentially filled and an equivalent flow may be formed through each aperture 425. Any number of apertures 425 may be formed about the mounting block including greater than or about 5, greater than or about 10, greater than or about 15, greater than or about 20, greater than or about 30, greater than or about 40, greater than or about 50, or more. The flow paths may produce an air curtain between the processing chamber and remote plasma unit. Because the volume may be substantially reduced from a volume extending from the remote plasma source, a controlled flow may be delivered that may produce a blocking flow for any back streaming materials.

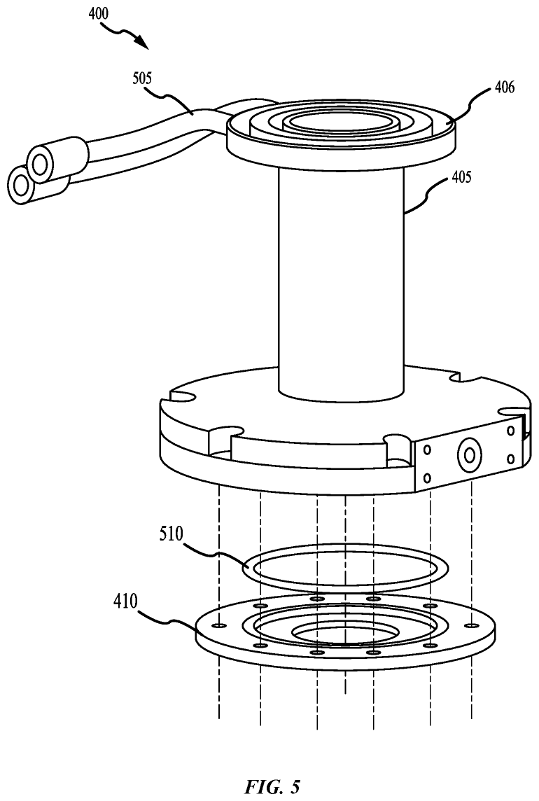

Turning to FIG. 5 is shown a schematic exploded view of exemplary adapter 400 according to some embodiments of the present technology. As illustrated, additional features of the adapter may be shown, which may provide additional functionality to the features of the adapter as described above. For example, within first surface 406 of mounting block 405, may be a recess formed within the surface. A fluid tube 505 may be seated within the recess, which may deliver a fluid for cooling a base of a remote plasma unit seated on the first surface 406 of the adapter 400. Additionally, an elastomeric element 510, such as an o-ring, may be seated between the mounting plate 410 and the mounting block 405. The elastomeric element may be seated radially outward of the recessed section of mounting plate 410, which may ensure fluid isolation of materials delivered through the mounting block in embodiments of the present technology.

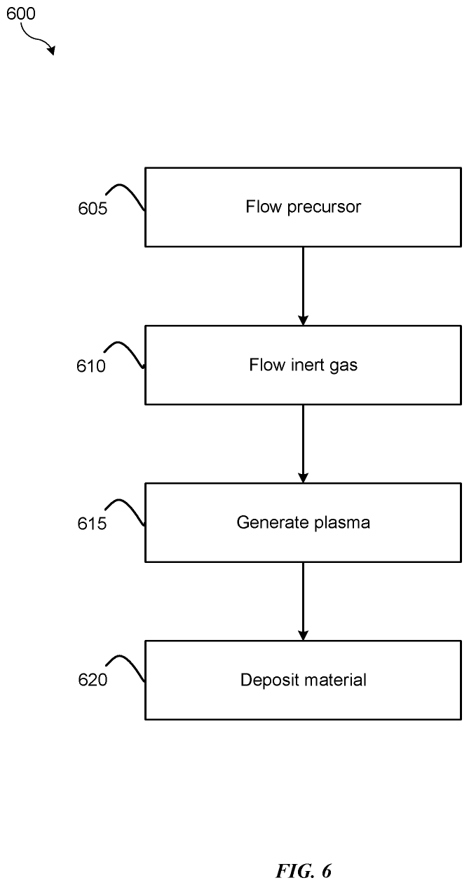

Turning to FIG. 6 is shown operations of an exemplary method 600 of semiconductor processing according to some embodiments of the present technology. The method may be performed in a variety of processing chambers, including processing system 200 or processing system 300 described above, which may include adapter assemblies or components according to embodiments of the present technology, such as any adapter or adapter components or characteristics as discussed previously. Method 600 may include a number of optional operations, which may or may not be specifically associated with some embodiments of methods according to the present technology.

Method 600 may include a processing method that may include operations for forming a hardmask film or other deposition operations. The method may include optional operations prior to initiation of method 600, or the method may include additional operations. For example, method 600 may include operations performed in different orders than illustrated. In some embodiments, method 600 may include flowing one or more precursors into a processing chamber at operation 605. For example, the precursor may be flowed into a chamber, such as included in system 200, and may flow the precursor through one or more of a gasbox, a blocker plate, or a faceplate, prior to delivering the precursor into a processing region of the chamber to interact with a substrate seated on a substrate support. In some embodiments the precursor may be or include a carbon-containing precursor, a silicon-containing precursor, or any other deposition precursor, although any other deposition processes, etching processes, or other processes may similarly be performed.

In some embodiments, an adapter including a mounting block and a mounting plate may be included in the system at an exterior region of the processing chamber, as previously described. Any of the other characteristics of adapters described previously may also be included, including any aspect of adapter 400 described above. As discussed above, the chamber in which the process is being performed may produce a planar temperature skew across the substrate due to characteristics of the chamber. At operation 610 an inert gas may be flowed into a region defined by a bypass device between the processing chamber and a remote plasma unit. For example, an adapter as previously described may provide a volume affording access for a purge gas to be flowed to produce an air curtain to control back streaming within the chamber. The adapter may include any of the features, components, or characteristics of adapters as previously described.

At operation 615, a plasma may be generated of the precursors within the processing region, such as by providing RF power to the faceplate to generate a plasma. Material formed in the plasma, such as a carbon-containing material or a silicon-containing material, may be deposited on the substrate at operation 620. An inert gas may be flowed through an adapter and the flow rate may be adjusted to control and prevent back streaming or plasma effluents or materials into a remote plasma system unit. By utilizing adapters as described above, the present technology may provide protection of a remote plasma source, while limiting the inclusion of additional components upstream of the processing chamber. These configurations may allow an air curtain to be produced with a purge gas, as well as controlling a fluid flow into the processing chamber, which may otherwise affect deposition or other processing conditions.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a channel” includes a plurality of such channels, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a remote plasma source;
a processing chamber, wherein the processing chamber comprises a gasbox defining an access into the processing chamber; and
an adapter positioned between the remote plasma source and the processing chamber, wherein the adapter comprises:
a mounting block defining a central aperture, wherein the remote plasma source is seated on a first surface of the mounting block, and
a mounting plate, wherein the mounting plate is characterized by a first surface on which the mounting block is seated, wherein the mounting plate defines a central aperture axially aligned with the central aperture defined through the mounting block, wherein the mounting plate defines a recess in the first surface of the mounting plate extending about the central aperture through the mounting plate, and wherein the recess forms a volume between the mounting block and the mounting plate.

2. The semiconductor processing system of claim 1, wherein the mounting block comprises:
a first mounting block member on which the remote plasma source is seated, wherein the first mounting block member defines a recess extending circumferentially about an outer surface of the first mounting block member; and
a second mounting block member coupled with the first mounting block member, wherein the second mounting block member is seated on the mounting plate, and wherein the second mounting block member defines an aperture fluidly accessing the recess defined in the first mounting block member.

3. The semiconductor processing system of claim 2, wherein the first mounting block member is characterized by a second surface opposite the first surface of the mounting block, and wherein the first mounting block member defines a plurality of apertures extending from the recess defined in the first mounting block member to the second surface of the first mounting block member.

4. The semiconductor processing system of claim 3, wherein the plurality of apertures provide fluid access to the volume formed between the mounting block and the mounting plate.

5. The semiconductor processing system of claim 4, wherein the plurality of apertures defined in the first mounting block member are fluidly accessible to the aperture defined through the second mounting block member via the recess defined circumferentially about the first mounting block member.

6. The semiconductor processing system of claim 2, wherein the recess defined circumferentially about the first mounting block member comprises a first recess portion and a second recess portion, wherein the first recess portion extends to a greater distance within the first mounting block member than the second recess portion.

7. The semiconductor processing system of claim 6, wherein the second mounting block member couples with the first mounting block member to provide a flow path between the second recess portion and the first recess portion.

8. The semiconductor processing system of claim 7, wherein the first recess portion is vertically offset from the aperture through the second mounting block member, and wherein the first recess portion is fluidly accessible from the aperture through the second mounting block member via the second recess portion.

9. The semiconductor processing system of claim 2, further comprising a valve providing fluid access to the aperture defined in the second mounting block member.

10. A semiconductor processing chamber adapter, comprising:
a mounting block defining a central aperture, wherein the mounting block is characterized by a first surface and a second surface opposite the first surface; and
a mounting plate defining a central aperture axially aligned with the central aperture of the mounting block, wherein:
the mounting plate is characterized by a first surface and a second surface opposite the first surface,
the second surface of the mounting block is seated on the first surface of the mounting plate,
the mounting plate defines a recess in the first surface of the mounting plate extending about the central aperture through the mounting plate, and
the recess forms a volume between the mounting block and the mounting plate.

11. The semiconductor processing chamber adapter of claim 10, wherein the mounting block comprises:
a first mounting block member, wherein the first mounting block member defines a recess extending circumferentially about an outer surface of the first mounting block member; and
a second mounting block member coupled with the first mounting block member, wherein the second mounting block member is seated on the mounting plate, and wherein the second mounting block member defines an aperture fluidly accessing the recess defined in the first mounting block member.

12. The semiconductor processing chamber adapter of claim 11, wherein the first mounting block member is characterized by a second surface opposite the first surface of the mounting block, and wherein the first mounting block member defines a plurality of apertures extending from the recess defined in the first mounting block member to the second surface of the first mounting block member.

13. The semiconductor processing chamber adapter of claim 12, wherein the plurality of apertures provide fluid access to the volume formed between the mounting block and the mounting plate.

14. The semiconductor processing chamber adapter of claim 13, wherein the plurality of apertures defined in the first mounting block member are fluidly accessible to the aperture defined through the second mounting block member via the recess defined circumferentially about the first mounting block member.

15. The semiconductor processing chamber adapter of claim 11, wherein the recess defined circumferentially about the first mounting block member comprises a first recess portion and a second recess portion, and wherein the first recess portion extends to a greater distance within the first mounting block member than the second recess portion.

16. The semiconductor processing chamber adapter of claim 15, wherein the second mounting block member couples with the first mounting block member to provide a flow path between the second recess portion and the first recess portion.

17. The semiconductor processing chamber adapter of claim 16, wherein the first recess portion is vertically offset from the aperture through the second mounting block member, and wherein the first recess portion is fluidly accessible from the aperture through the second mounting block member via the second recess portion.

18. A method of semiconductor processing comprising:
flowing a precursor into a processing region of a semiconductor processing system, wherein a substrate is seated on a substrate support within the processing region of a semiconductor processing chamber of the semiconductor processing system;
flowing an inert gas into a region defined between a remote plasma source and the semiconductor processing chamber, the region comprising a bypass device, wherein the bypass device comprises an adapter positioned between the remote plasma source and the semiconductor processing chamber, wherein the adapter comprises:
a mounting block defining a central aperture, wherein the remote plasma source is seated on a first surface of the mounting block, and
a mounting plate, wherein the mounting plate is characterized by a first surface on which the mounting block is seated, wherein the mounting plate defines a central aperture axially aligned with the central aperture defined through the mounting block, and wherein flowing the inert gas forms an air curtain in the central aperture of the mounting plate between the processing chamber and the remote plasma source;
generating a plasma of the precursor within the processing region of the semiconductor processing chamber; and
depositing a material on the substrate.

19. The method of claim 18, wherein the mounting plate defines a recess in the first surface of the mounting plate extending about the central aperture through the mounting plate, wherein the recess forms a volume between the mounting block and the mounting plate.

20. The method of claim 18, further comprising:
adjusting a flow rate of the inert gas using an adjustable valve of the bypass device to adjust the air curtain to prevent back diffusion into the remote plasma source.
